(19) United States
(12) Patent Application Publication
(10) Pub. No.: US 2025/0270695 A1
(43) Pub. Date: Aug. 28, 2025

(54) METHODS, STRUCTURES, AND SYSTEMS FOR LITHOGRAPHIC PATTERNING

(71) Applicant: ASM IP Holding B.V., Almere (NL)

(72) Inventors: Kishan Ashokbhai Patel, Leuven (BE); Steaphan Mark Wallace, Tama City Tokyo (JP); Dennis Christy Peter Raj, Vantaa (FI); Yiting Sun, Leuven (BE); Yoann Tomczak, Leuven (BE); Charles Dezelah, Helsinki (FI); David Kurt De Roest, Leuven (BE); Fatemeh Davodi, Helsinki (FI)

(21) Appl. No.: 19/059,061

(22) Filed: Feb. 20, 2025

Related U.S. Application Data
(60) Provisional application No. 63/556,513, filed on Feb. 22, 2024.

(51) Int. Cl. C23C 16/455; C23C 16/26; C23C 16/44; C23C 16/56; H01L 21/02; H01L 21/027

(52) U.S. Cl. CPC C23C 16/45536; C23C 16/26; C23C 16/4408; C23C 16/45553; C23C 16/56; H01L 21/02274; H01L 21/0228; H01L 21/0274

(57) ABSTRACT

Methods, related structures, and related systems for lithography, particularly extreme ultraviolet lithography (EUV). Presently disclosed methods can comprise forming a carbon underlayer having a high sp3 carbon content. Presently disclosed methods can comprise forming a carbon underlayer by means of a cyclical deposition process such as plasma-enhanced atomic layer deposition.

### CROSS-REFERENCE TO RELATED APPLICATION(S)

This Application claims the benefit of U.S. Provisional Application 63/556,513 filed on Feb. 22, 2024, the entire contents of which are incorporated herein by reference.

### FIELD OF INVENTION

The present disclosure is in the field of integrated circuit manufacturing, especially in the field of lithography.

### BACKGROUND OF THE DISCLOSURE

Compared to previous UV lithography methods, EUV lithography resolution is improved through decreased wavelength which also increases the photon energy and therefore energy consumption is greatly increased. To reduce the dose, either the photon flux or the exposure time needs to be decreased, both of which reduces the total number of photons hitting the lithography resists to very low amounts. Moreover, high energy EUV photons are more difficult to absorb by most materials, exaggerating the issue of the low photon count. With such a low amount of photons absorbed by the resist, it is difficult to obtain a good quality lithography structure due to the photon shot noise effect, especially at the small structure sizes being pursued. Therefore, the key to practically decreasing dose is to increase the useful effect of the limited photons received

EUV resists are being continuously improved to increase the material absorption of each photon, and increased the number of electrons produced per photon. Absorption is often improved by inserting EUV absorbing materials into the lithography structure which produce excited electrons, and the number of secondary electrons is increased by creating electron cascades to produce many lower energy electrons to initiate chemical changes in the resist. Current resists have been optimized to maximize these effects and absorb most of the photons. However, there remains a need for further dose lowering.

Amorphous carbon layers are used in lithography, e.g., EUV lithography. These are applied using high through put methods with a high growth rate such as one or more of spin coating, flowable deposition, and plasma-enhanced chemical vapor deposition. Such methods yield hard masks that do not offer a dose reduction effect for EUV lithography. “dose” refers to the photon energy needed for fully developing a resist. “dose reduction” refers to a reduction of the required dose for a particular lithography solution compared to a reference.

Typically in the industry a continuous deposition of carbon is used (spin-on, flowable, PECVD) to achieve high throughput. However, these depositions show no dose reduction effect.

### SUMMARY OF THE DISCLOSURE

Described herein is a method of forming an underlayer for lithographic patterning, the method comprising providing a substrate to a reaction chamber; and, executing a cyclical deposition process, the cyclical deposition process comprising a plurality of deposition cycles, ones from the plurality of deposition cycles comprising a precursor pulse that comprises exposing the substrate to a precursor, ones from the plurality of deposition cycles further comprising a reactant pulse that comprises exposing the substrate to a reactant; wherein the underlayer comprises carbon.

In some embodiments, least 50 atomic percent of the carbon comprised in the underlayer is sp3 carbon.

In some embodiments, the precursor comprises an aromatic compound.

In some embodiments, the precursor is selected from the list consisting of benzene, alkylbenzene, toluene, ethylbenzene, xylene, durene, aniline, phenol, benzoic acid, biphenyl, mesitylene, styrene, toluidine, toluic acid, cresol, and, naphthalene.

In some embodiments, the precursor comprises 1,2,4-trimethylbenzene.

In some embodiments, the precursor comprises an alkane.

In some embodiments, the precursor comprises octane.

In some embodiments, the reactant pulse comprises generating a plasma and

wherein the reactant comprises one or more plasma-generated species

In some embodiments, the plasma employs a plasma gas that comprises a noble gas.

In some embodiments the noble gas comprises argon.

In some embodiments, the plasma gas further comprises hydrogen.

In some embodiments, the underlayer substantially consists of amorphous carbon.

In some embodiments, ones from the plurality of deposition cycles further comprise a post precursor purge, the post precursor purge being executed after the precursor pulse.

In some embodiments, ones from the plurality of deposition cycles further comprise a post reactant purge, the post reactant purge being executed after the reactant pulse.

In some embodiments, the cyclical deposition results in an initial underlayer having an initial sp3 carbon content, wherein the process is followed by subjecting the substrate to a treatment step, the treatment step resulting in a treated underlayer having a treated sp3 carbon content, the treated sp3 carbon content being larger than the initial sp3 carbon content.

In some embodiments, the treatment step comprises a plasma treatment step that comprises generating a treatment plasma, and exposing the substrate to one or more active treatment species.

In some embodiments, the treatment plasma comprises one or more of an argon plasma and an oxygen plasma.

In some embodiments, the reactant pulse comprises a plurality of micro reactant pulses.

Further described is a structure comprising a substrate, an underlayer overlying the substrate, and a photosensitive layer overlying the underlayer, wherein the underlayer is formed by means of a method according to an embodiment of the present disclosure.

Further described herein is a system comprising a reaction chamber, a substrate support, and a controller that is constructed and arranged for causing the system to execute a method as described herein.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIG. 1 shows an embodiment of a structure 100.

FIGS. 2 and 3 show experimental results.

FIGS. 4 and 5 show systems according to embodiments of the present disclosure.

FIGS. 6 and 7 illustrate methods according to embodiments of the present disclosure.

FIGS. 8 to 12 illustrate cyclical deposition processes according to embodiments of the present disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide. In some embodiments, the substrate can have an OH termination. The OH termination can occur natively, e.g., it can occur through atmospheric oxidation, or the OH termination can be provided intentionally, e.g., by subjecting the substrate to a plasma treatment.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

Described herein is a method of forming an underlayer for lithographic patterning.

The method comprises providing a substrate to a reaction chamber. The method further comprises executing a cyclical deposition process. The cyclical deposition process comprises a plurality of deposition cycles. Ones from the plurality of deposition cycles comprise a precursor pulse that comprises exposing the substrate to a precursor. Ones from the plurality of deposition cycles further comprise a reactant pulse that comprises exposing the substrate to a reactant. The underlayer comprises carbon.

Exposure of substrate to precursor can result in one or more of physisorption and chemisorption of at least one of precursor and precursor fragments on the substrate. Ones from the plurality of reactant pulses can result in one or more of physisorption and chemisorption of at least one of reactant and reactant fragments on the substrate.

An underlayer according to an embodiment of the present disclosure is advantageously formed using a cyclical deposition process such as atomic layer deposition. It shall be noted that experiments indicated that carbon underlayers formed using 1,2,4-trimethylbenze as a precursor showed dose reduction when formed employing a cyclical vapor deposition process, in particular plasma-enhanced atomic layer deposition (PE-ALD). Conversely-carbon films formed using the same precursor and but using non-cyclical plasma-enhanced chemical vapor deposition (PE-CVD) did not show dose reduction. This is a clear indication that underlayers according to embodiments of the present disclosure are superior compared to underlayers formed using non-cyclical PE-CVD.

Advantageously, methods according to embodiments of the present disclosure can offer dose reduction for EUV lithography. Additionally, methods according to embodiments of the present disclosure can provide carbon underlayers that have more sp3 carbon than sp2 carbon. Advantageously, methods according to embodiments of the present disclosure can offer a growth rate of less than 1 nm/second.

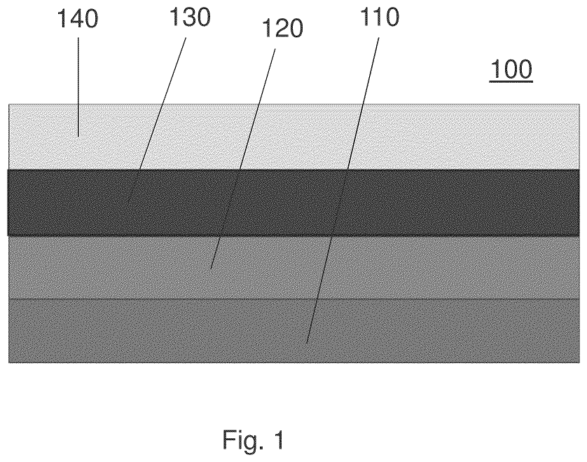

An exemplary structure 100 for EUV lithography is described referring to FIG. 1. The structure 100 comprises a substrate 110. The substrate 110 is covered with an ashable hard mask 120. The ashable hard mask 120 can comprise amorphous carbon that is deposited by means of plasma enhanced chemical vapor deposition and that comprises a relatively high concentration of sp2 hybridized carbon, e.g., more than 70 atomic percent sp2 hybridized carbon. On top of the ashable hard mask 120 lies an underlayer 130 according to an embodiment according to the present disclosure. On top of the underlayer 130 lies an EUV resist 140, e.g., a metalorganic resist.

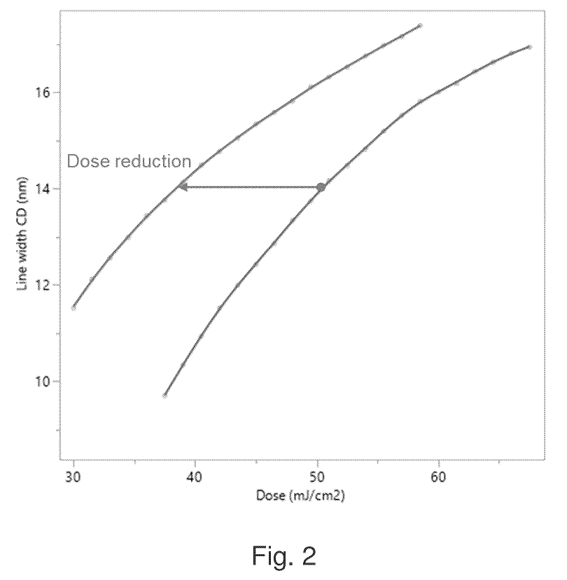

FIG. 2 shows experimental results indicating that less dose is needed during EUV lithography when an underlayer according to an embodiment of the present disclosure is employed, i.e., using a structure according to the embodiment of FIG. 1, compared to a similar structure without the underlayer 130.

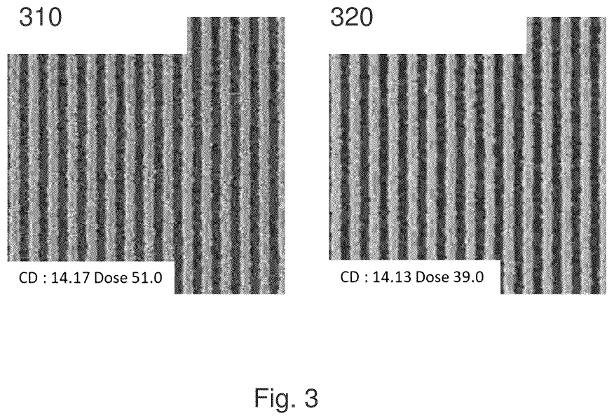

FIG. 3 shows a developed pattern using a reference structure 310 without underlayer according to an embodiment of the present disclosure, and a sample structure 320 according to the embodiment of FIG. 1 that comprises an underlayer according to an embodiment of a method of the present disclosure. It shows electron micrographs that indicate that an underlayer according to an embodiment of the present disclosure can yield similar pattern quality for a lower dose.

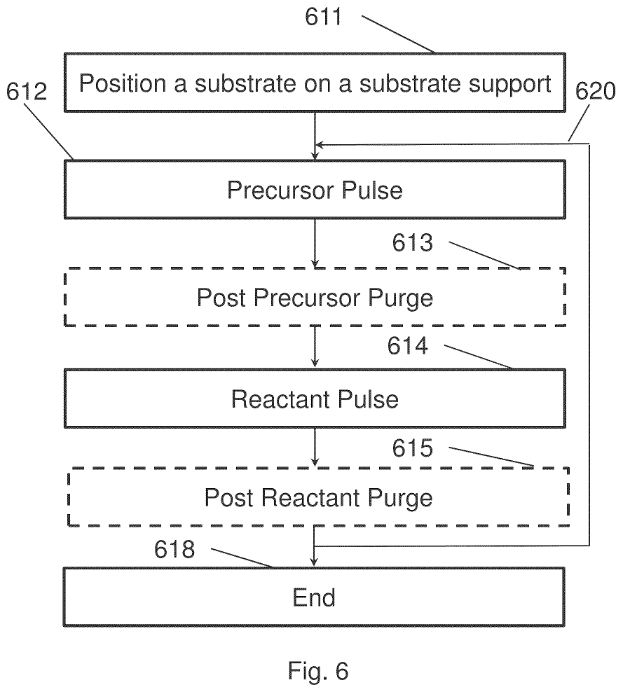

FIG. 6 illustrates an embodiment of a method as described herein. The method comprises a step 611 of positioning a substrate on a substrate support. Then, the method comprises executing 612 a precursor pulse. The precursor pulse comprises exposing the substrate to a precursor. Any suitable precursor as described herein can be used during the precursor pulse. Optionally, a post precursor purge 613 is then carried out. The post precursor purge 613 comprises exposing the substrate to a purge gas. Then, the method comprises executing 614 a reactant pulse, though in some embodiments the reactant pulse can precede the precursor pulse. The reactant pulse comprises a step of exposing the substrate to a reactant. Suitable reactants are described elsewhere herein and include molecules and plasma-generated species such as ions and radicals. After the reactant pulse, the method optionally comprises executing 615 a post reactant purge. The precursor pulse 612, the reactant pulse 614, and their respective optional purges 613, 615 are repeated 620 one or more times until a material having a desired thickness has been deposited. After an underlayer having a desired thickness has been deposited, the method ends 618.

An underlayer according to an embodiment of the present disclosure can comprise carbon in various phases, crystal structures, and/or morphologies. For example, the carbon comprise one or more of cubic/diamond (sp3) carbon, hexagonal/Lonsdaleite (sp3) carbon, graphitic (sp2) carbon, a-C:H, nanocrystalline graphitic carbon (sp2), fullerene (sp2) carbon, and amorphous (sp3+sp2) carbon.

In some embodiments, an underlayer formed according to an embodiment of the present disclosure has a polar surface energy of 1-5 or 1-3 mJ/m² and a dispersive surface energy of 35-40mJ/m². This should be compared to prior art amorphous carbon hard masks which may have a polar surface energy of ˜17mJ/m² and a dispersive surface energy of ˜38mJ/m².

In some embodiments, at least 50 atomic percent of the carbon comprised in the underlayer is sp3 carbon. In some embodiments, at least 60, 70, 80, 90, 95, or 99 atomic percent of the carbon comprised in the underlayer is sp3 carbon.

Advantageously, underlayers formed using embodiments of methods according to the present disclosure exhibit good etch contrast with metalorganic resist. Advantageously, underlayers formed using embodiments of methods according to the present disclosure exhibit dose reduction. Advantageously, underlayers formed using embodiments of methods according to the present disclosure exhibit low line roughness.

In some embodiments, the underlayer comprises one or more of amorphous carbon, microcrystalline carbon, polycrystalline carbon, carbon-containing polymers, carbon-containing oligomers, and carbon-containing cross-linked resins.

In some embodiments, the precursor comprises an aromatic compound.

In some embodiments, the precursor is selected from the list consisting of benzene, alkylbenzene, toluene, ethylbenzene, xylene, durene, aniline, phenol, benzoic acid, biphenyl, mesitylene, styrene, toluidine, toluic acid, cresol, and, naphthalene. In some embodiments, the precursor is selected from the list consisting of o-xylene, m-xylene, p-xylene. Same applies for toluic acid and cresol.

In some embodiments, the precursor comprises an alkylbenzene. In some embodiments, the alkylbenzene comprises trimethylbenzene. In some embodiments, the alkylbenzene comprises 1,2,4-trimethylbenzene.

In some embodiments, the precursor comprises a hydrocarbon. In some embodiments, the precursor comprises an alkane. In some embodiments, the precursor comprises a linear alkane. In some embodiments, the precursor comprises a branched alkane. In some embodiments, the precursor comprises one or more of methane, ethane, propane, butane, pentane, hexane, heptane, octane, nonane, and decane.

In some embodiments, the precursor comprises an aliphatic hydrocarbon.

In some embodiments, the precursor comprises bicyclo [2.2.2]octane. In some embodiments, the bicyclo [2.2.2]octane comprises one or more reactive substituents, e.g., in the 1- or 1,4-positions. Suitable reactive substituents can be selected from the list consisting of —F, —Cl, —Br, —I, —OH, —CH₂OH, —NH₂, —CH₂NH₂, —PH₂, —CH₂PH₂, —CH₂SH, —SH, —CHO, —COOH, and —COCl.

In some embodiments, employing such a precursor can increase the sp3 carbon content in the underlayer.

In some embodiments, the precursor comprises cubane. In some embodiments, the cubane comprises one or more reactive substituents, e.g., in the 1 - or 1,4-positions. Suitable reactive substituents can be selected from the list consisting of —F, —Cl, —Br, —I, —OH, —CH₂OH, —NH₂, —CH₂NH₂, —PH₂, —CH₂PH₂, —CH₂SH, —SH, —CHO, —COOH, and —COCl. In some embodiments, employing such a precursor can increase the sp3 carbon content in the underlayer.

In some embodiments, the precursor comprises neopentane. In some embodiments, the neopentane comprises one or more reactive substituents on the terminal carbon atoms. Suitable reactive substituents can be selected from the list consisting of —F, —Cl, —Br, —I, —OH, —CH₂OH, —NH₂, —CH₂NH₂, —PH₂, —CH₂PH₂, —CH₂SH, —SH, —CHO, —COOH, and —COCl. In some embodiments, employing such a precursor can increase the sp3 carbon content in the underlayer.

In some embodiments, the precursor comprises a single arene ring. In some embodiments, the single arene ring comprises one or more reactive substituents. In some embodiments, the one or more reactive substituents can be selected from the list consisting of —F, —Cl, —Br, —I, —CH₂F, —CH₂Cl, —CH₂Br—, —CH₂I, —OH, —CH₂OH, —NH₂, —CH₂NH₂, —PH₂, —CH₂PH₂, —CH₂SH, —SH, —CHO, —COOH, and —COCl. In some embodiments, such a precursor can increase the sp2 carbon content in the underlayer.

In some embodiments, the precursor comprises two or more fused arene rings, i.e., where each ring contains one or more carbon atoms that also are contained in another arene ring. In some embodiments, such a precursor comprises one or more reactive substituents. In some embodiments, the one or more reactive substituents can be selected from the list consisting of —F, —Cl, —Br, —I, —H₂F, —CH₂Cl, —CH₂Br—, —CH₂I, —OH, —CH₂OH, —NH₂, —CH₂NH₂, —PH₂, —CH₂PH₂, —CH₂SH, —SH, —CHO, —COOH, and —COCl. In some embodiments, such a precursor can increase the sp2 carbon content in the underlayer.

In some embodiments, the precursor comprises a fullerene. In some embodiments, such a precursor comprises one or more reactive substituents. In some embodiments, the one or more reactive substituents can be selected from the list consisting of —F, —Cl, —Br, —I, —CH₂F, —CH₂Cl, —CH₂Br—, —CH₂I, —OH, —CH₂OH, —NH₂, —CH₂NH₂, —PH₂, —CH₂PH₂, —CH₂SH, —SH, —CHO, —COOH, and —COCl. In some embodiments, such a precursor can increase the sp2 carbon content in the underlayer.

In some embodiments, the precursor comprises a diene. The diene can comprise two carbon-carbon double bonds. In some embodiments, such a precursor comprises one or more reactive substituents. In some embodiments, the one or more reactive substituents can be selected from the list consisting of —F, —Cl, —Br, —I, —CH₂F, —CH₂Cl, —CH₂Br—, —CH₂I, —OH, —CH₂OH, —NH₂, —CH₂NH₂, —PH₂, —CH₂PH₂, —CH₂SH, —SH, —CHO, —COOH, and —COCl. In some embodiments, such a precursor can increase the sp2 carbon content in the underlayer.

In some embodiments, the precursor comprises an allene. In some embodiments, such a precursor comprises one or more reactive substituents. In some embodiments, the one or more reactive substituents can be selected from the list consisting of —F, —Cl, —Br, —I, —CH₂F, —CH₂Cl, —CH₂Br—, —CH₂I, —OH, —CH₂OH, —NH₂, —CH₂NH₂, —PH₂, —CH₂PH₂, —CH₂SH, —SH, —CHO, —COOH, and —COCl. In some embodiments, such a precursor can increase the sp2 carbon content in the underlayer.

In some embodiments, the precursor comprises an alkyne. In some embodiments, such a precursor comprises one or more reactive substituents. In some embodiments, the one or more reactive substituents can be selected from the list consisting —F, —Cl, —Br, —I, —CH₂F, —CH₂Cl, —CH₂Br—, —CH₂I, —OH, —CH₂OH, —NH₂, —CH₂NH₂, —PH₂, —CH₂PH₂, —CH₂SH, —SH, —CHO, —COOH, and —COCl. In some embodiments, such a precursor can increase the sp2 carbon content in the underlayer.

In some embodiments, the precursor comprises a compound having the general formula

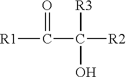

with R1, R2, and R3 being independently selected from H and hydrocarbyl. In some embodiments, R3 is H and R1 and R2 are independently selected from H and hydrocarbyl. In some embodiments, the hydrocarbyl is selected from alkyl, alkenyl, alkynyl, and aryl. In some embodiments, R3 is H, R1 is aryl, and R2 is alkyl. In some embodiments, R2 and R3 are equal. In some embodiments, R1 is aryl, and R2 and R3 are methyl. In some embodiments, the precursor comprises 2-hydroxy-2-methylpropiophenone.

In some embodiments, the precursor is selected from an alkylbenzene such as 1,2,4-trimethylbenze and an organic acid anhydride such as 2-hydroxy-2-methylpropiophenone.

In some embodiments, the underlayer comprises a polyimide. In some embodiments, the underlayer consists substantially only of polyimide. In some embodiments, the underlayer comprises polyamic acid. In some embodiments, the underlayer consists substantially only of polyamic acid and polyimide. In some embodiments, the underlayer is deposited at temperatures below 190° C., and subsequently heat-treated (annealed) at a temperature of about 190° C. or higher (such as from about 200° C. to about 500° C.) to increase the proportion of the organic polymer from polyamic acid to polyimide. In some embodiments, the underlayer comprises one or more of dimers, trimers, polyurethanes, polythioureas, polyesters, polyimines, other polymeric forms or mixtures of the above materials.

In some embodiments, the underlayer may be formed by means of a thermal cyclical deposition process such as molecular layer deposition (MLD). In some embodiments, the underlayer comprises an organic polymer. In some embodiments, the underlayer substantially consists of an organic polymer. The deposition of an organic polymer according to the current disclosure can be performed by a cyclic vapor deposition process. For example, the deposition of the organic polymer may be an MLD process. The deposition of an organic polymer can comprise providing a first vapor-phase organic precursor into a reaction chamber and providing a second vapor-phase organic precursor into the reaction chamber. Providing the first vapor-phase organic precursor and providing the second vapor-phase organic precursor may define a deposition cycle. The deposition cycle may be repeated until a suitable thickness of the organic polymer has been deposited on the substrate.

In some embodiments, the organic polymer comprises polyimide. In some embodiments, the organic polymer comprises polyamide. In some embodiments, the organic polymer comprises one or more of polyurea, polyurethane, polythiourea, polyester, and polyimine.

In some embodiments, the precursor comprises a double carboxylic acid anhydride. In some embodiments, the double carboxylic acid anhydride comprises pyromellitic dianhydride. In some embodiments, the precursor comprises an anhydride, such as furan-2,5-dione (maleic acid anhydride). The anhydride can be a dianhydride, e.g., pyromellitic dianhydride (PMDA). In some embodiments, the precursor can be any other monomer with two reactive groups which will react with the reactant.

In some embodiments, the precursor is selected from Ethylenediaminetetraacetic Dianhydride, 1,2,4,5-Cyclohexanetetracarboxylic Dianhydride, 1,2,3,4-butanetetracarboxylic dianhydride, Bicyclo[2.2.2]oct-7-ene-2,3,5,6-tetracarboxylic Dianhydride, 4,4′-Biphthalic Anhydride, 1,2,3,4-Cyclobutanetetracarboxylic Dianhydride, and 3-(Carboxymethyl)-1,2,4-cyclopentanetricarboxylic Acid 1,4:2,3-dianhydride.

In some embodiments, the precursor comprises pyromellitic dianhydride (PMDA).

In some embodiments, the reactant comprises a diamine. In some embodiments, the diamine is selected from the list consisting of 1,6-diaminohexane, 1,4-diaminocyclohexane, and 1,4-diaminobenzene.

In some embodiments, the diamine is selected from the list consisting of 1,2-diaminoethane, 1,3-diaminopropane, 1,4-diaminobutane, 1,5-Diaminopentane, 1,7-diaminoheptane, 1,8-diaminooctane, 1,4-Bis(aminomethyl)cyclohexane, 2-Methyl-1,5-pentanediamine, 2,2-Dimethyl-1,3-propanediamine, 1,3-Propanediamine, Propylenediamine, 2-Methyl-1,3-propanediamine, 2-Methyl-1,5-pentanediamine, 1,3-Pentanediamine, and 1,2-Pentanediamine.

In some embodiments, the reactant can comprise, for example, 1,6-diaminohexane, 1,3-diaminopentane, triamine, such as tris(2-aminoethyl)amine, or a cyclic compound comprising at least two primary amine groups, such as 1,4-diaminocyclohexane or p-phenylenediamine. In some embodiments, the substrate is contacted with the reactant before it is contacted with the precursor. In some embodiments, the substrate is contacted with the precursor before it is contacted with the reactant.

In some embodiments, the precursor comprises a dianhydride. A dianhydride may be, for example, pyromellitic dianhydride (PMDA).

In some embodiments, the reactant comprises at least two carbon atoms, such as 1,2-diaminoethane. In some embodiments, the reactant comprises three carbon atoms. In some embodiments, the reactant comprises four carbon atoms. For example, the reactant comprises may be selected from 1,2-diaminobutane, 1,3-diaminobutane, 1,4-diaminobutane and 2,4-diaminobutane. Thus, in some embodiments, at least one of the amino groups is attached to a carbon atom that is bonded to two other carbon atoms. In other words, at least one of the amino groups may be located at the end of a carbon chain. In some embodiments, a diamine comprises five carbon atoms. In some embodiments, a diamine comprises six carbon atoms.

In some embodiments, the reactant comprises a C2 to C11 compound. The number of carbon atoms in the reactant typically influences the volatility of the compound such that a higher-weight compound may not be as volatile as a smaller compound. However, it was found out that intermediate-sized reactants containing, for example, four, five or six carbon atoms, may have suitable properties for being used as a reactant in some embodiments of methods according to the current disclosure. For example, 1,3-diaminopentane is liquid at room temperature, has a boiling point of 164° C. under atmospheric pressure, a vapor pressure of about 2.22 Torr at 25° C. and reaches a vapor pressure of 1 Torr at temperatures below 20° C. Thus, when 1,3-diaminopentane is used as a precursor for organic polymer deposition according to the current disclosure, the precursor vessel does not need to be heated. This may be advantageous for the on-tool lifetime of the precursor, as it may be less prone to degradation during continued use. Further, a liquid precursor has an advantage that precursor vessel loading is less expensive than for solid precursors. In some embodiments, the reactant comprises 1,3-diaminopentane.

In some embodiments of the disclosure, the amine groups comprised in the reactants are attached to non-adjacent carbon atoms. This may have advantages for the availability for the amine groups to reactions with the second precursor. In some embodiments, there is one carbon atom between the amino group-binding carbon atoms. In some embodiments, there is at least one carbon atom between the amino group-binding carbon atoms. In some embodiments, there are two carbon atoms between the amino group-binding carbon atoms. In some embodiments, there are at least two carbon atoms between the amino group-binding carbon atoms. In some embodiments, there are three carbon atoms between the amino group-binding carbon atoms. In some embodiments, there are at least three carbon atoms between the amino group-binding carbon atoms. In some embodiments, there are four carbon atoms between the amino group-binding carbon atoms. In some embodiments, there are at least four carbon atoms between the amino group-binding carbon atoms.

In some embodiments, the reactant comprises 1,5-diamino-2-methylpentane. Although the vapor pressure of 1,5-diamino-2-methylpentane is lower than that of 1,3-diaminopentane, it is also liquid at ambient temperature, and reaching vapor pressure of 1 Torr requires a moderate temperature of about 40° C.

In some embodiments, a carbon atom bonded with an amine nitrogen in the reactant is bonded to at least two carbon atoms. In some embodiments, the reactant comprises a secondary amine. In some embodiments, the reactant comprises a tertiary amine. Thus, in some embodiments in which the reactant comprises five or more carbons, at least one of the amino groups may be located away from the end of a carbon chain. The structure of the reactant affects its properties in a vapor deposition process. Branching of a reactant, including the number of branches, and the relative position of the amino groups to the branches, may cause the deposited organic polymer to have different properties. Without limiting the current disclosure to any specific theory, for example steric factors, may lead to certain reactions being preferred in This may offer the possibility to design a deposition process for a given purpose, taking into account for example the thermal budget, organic polymer growth speed requirements, necessary degree of selectivity, by using different reactants.

In some embodiments, the reactant comprises a cyclic diamine. In some embodiments, the reactant comprises one or more of a cyclopentanedialkylamine, cyclohexanedialkylamine, cyclopentadienedialkylamine, benzenedialkylamine, cyclopentanetrialkylamine, cyclohexanetrialkylamine, cyclopentadienetrialkylamine and benzenetrialkylamine.

In some embodiments, the reactant comprises an aromatic diamine. In some embodiments, the aromatic diamine is a diaminobenzene, such as 1,2-diaminobenzene, 1,3-diaminobenzene, or 1,4-diaminobenzene. In some embodiments, the aromatic diamine comprises an alkylamino group in at least one position. For example, the alkylamino group may be a C1 to C3 alkylamino group, such as —CH₂NH₂, —(CH₂)₂NH₂, —(CH₂)₃NH₂, —CH(CH₃)NH₂ or —CH₂CH(CH₃)NH₂.

In some embodiments, the reactant is selected from a group consisting of 1,3-diaminopentane, 1,4-diaminopentane, 2,4-diaminopentane, 2,4-diamino-2,4-dimethylpentane, 1,5-diamino-2-methylpentane, 1,3-diaminobutane, 1,3-diamino-3-methylbutane, 2,5-diamino-2,5-dimethylhexane, 1,4-diamino-4-methylpentane, 1,3-diaminobutane, 1,5-diaminohexane, 1,3-diaminohexane, 2,5-diaminohexane, 1,3-diamino-5-methylhexane, 4,4,4-trifluoro-1,3-diamino-3-methylbutane, 2,4-diamino-2-methylpentane, 4-(1-methylethyl)-1,5-diaminohexane, 3-aminobutanamide, 1,3-diamino-2-ethylhexane, 2,7-diamino-2,7-dimethyloctane, 1,3-diaminobenzene and 1,4-diaminobenzene. In some embodiments, the reactant comprises a halogen.

In some embodiments, the reactant can comprise a triamine. Providing such molecules may advantageously affect the availability of polymerization sites for the precursor. Examples of suitable triamines include 1,2,3-triaminopropane, triamino butane (with amines in carbons 1, 2 and 3 or in carbons 1, 2 and 4), triamino pentane (especially with amines in carbons 1 and 5, plus in any one of the carbons 2, 3 or 4). Similarly, triamino hexanes may contain amine groups in carbons 1 and 6, as well as in any one of the positions 2, 3, 4 or 5; triamino heptanes may contain amine groups in carbons 1 and 7, as well as in any one of the positions 2, 3, 4, 5 or 6; and triamino octanes may contain amine groups in carbons 1 and 8, as well as in any one of the positions 2, 3, 4, 5, 6 or 7. Further, branched carbon chains, notably 2-aminomethyl-1,3-diaminopropane, 2-aminomethyl-1,4-diaminobutane (or alternatives having the two amino groups elsewhere in the butane chain), 2-aminomethyl-1,5-diaminopentane (or alternatives having the two amino groups elsewhere in the pentane chain), 3-aminomethyl-1,5-diaminopentane (or alternatives having the two amino groups elsewhere in the pentane chain), 2-aminomethyl-1,6-diaminohexane (or alternatives having the two amino groups elsewhere in the hexane chain), 3-aminomethyl-1,6-diaminohexane (or alternatives having the two amino groups elsewhere in the hexane chain), 3-aminoethyl-1,6-diaminohexane (or alternatives having the two amino groups elsewhere in the hexane chain). Also, an aromatic triamine, such as 1,3,5-triaminobenzene, may be an alternative for certain embodiments.

In some embodiments, the carbon chain of the reactant is branched. Thus, there is at least one carbon atom which is bonded to three or four other carbon atoms. In some embodiments, there is one such branching position in the reactant. In some embodiments, there are two such branching positions in the reactant. In some embodiments, there are three or more branching points. In some embodiments, the side chain from the longer carbon chain is a methyl group. In some embodiments, the side chain from the longer carbon chain is an ethyl group. In some embodiments, the side chain from the longer carbon chain is a propyl group. In some embodiments, the side chain from the longer carbon chain is an isopropyl group. In some embodiments, the side chain from the longer carbon chain is a butyl group. In some embodiments, the side chain from the longer carbon chain is a tert-butyl group. In some embodiments, a side chain of a reactant is a straight alkyl chain. In some embodiments, a side chain of a reactant is a branched alkyl chain. In some embodiments, a side chain of a reactant is a cyclic alkyl chain.

In some embodiments, the reactant may comprise two amino groups. In some embodiments, these amino groups may occupy one or both terminal positions on an aliphatic carbon chain. However, in some embodiments, they may not occupy either terminal position on an aliphatic carbon chain. In some embodiments, a reactant may comprise a diamine. In some embodiments, the reactant may comprise an organic precursor selected from the group of 1,2-diaminoethane, 1,3-diaminopropane, 1,4-diaminobutane, 1,5-diaminopentane, 1,2-diaminopropane, 2,3-butanediamine, 2,2-dimethyl-1,3-propanediamine. In some embodiments, the reactant is selected from the list consisting of 1,6-diaminohexane, 1,3-diaminopentane, triamine, such as tris(2-aminoethyl)amine, and a cyclic compound comprising at least two primary amine groups, such as 1,4-diaminocyclohexane or p-phenylenediamine.

In some embodiments, the precursor and reactant do not contain metal atoms. In some embodiments, the precursor and reactant do not contain semimetal atoms. In some embodiments, the precursor and reactant comprise metal or semimetal atoms. In some embodiments, the precursor and reactant contain carbon and hydrogen and one or more of the following elements: N, O, S, P, or a halogen, such as Cl or F.

In some embodiments, at least one of the precursor and the reactant may comprise an aliphatic compound comprising 1-6 carbon atoms, 2-5 carbon atoms, 2-4 carbon atoms, 5 or fewer carbon atoms, 4 or fewer carbon atoms, 3 or fewer carbon atoms, or 2 carbon atoms. In some embodiments, the bonds between carbon atoms in the reactant or precursor may be single bonds, double bonds, triple bonds, or some combination thereof.

In some embodiments, at least one of the precursor and the reactant has a vapor pressure greater than about 0.5 Torr, 0.1 Torr, 0.2 Torr, 0.5 Torr, 1 Torr, 2 Torr or greater at a temperature of about 20° C. or room temperature. In some embodiments, at least one of the precursor and the reactant has a boiling point less than about 400° C., less than 300° C., less than about 250° C., less than about 200° C., less than about 175° C., less than about 150° C., or less than about 100° C.

In some embodiments, at least one of the precursor and the reactant is a liquid precursor under standard conditions.

In some embodiments, ones from the plurality of deposition cycles can further comprise a dopant precursor pulse that comprises exposing the substrate to a dopant precursor. The dopant precursor comprises a dopant. Thus, an underlayer comprising the dopant can be formed. For example, the underlayer can comprise 0.1 to 1.0 atomic percent of the dopant, or 1.0 to 5.0 atomic percent of the dopant, or 5.0 to 20.0 atomic percent of the dopant.

In some embodiments, the dopant is selected from the list consisting of F, Ge, Cs, Bi, Sn, Hf, In, Sb, Te, Br, and I.

In some embodiments, and underlayer as described herein comprises hydrogen, for example from at least 1 atomic percent hydrogen to at most 10 atomic percent hydrogen, or from at least 10 atomic percent hydrogen to at most 20 atomic percent hydrogen, or from at least 20 atomic percent hydrogen to at most 30 atomic percent hydrogen, or from at least 30 atomic percent hydrogen to at most 40 atomic percent hydrogen, or from at least 40 atomic percent hydrogen to at most 50 atomic percent hydrogen, or from at least 50 atomic percent hydrogen to at most 60 atomic percent hydrogen.

Advantageously, an underlayer as described herein can have a high sp3 carbon content and a relatively high hydrogen content.

In some embodiments, the reactant pulse comprises exposing the substrate to microwaves while contacting the substrate with the reactant.

In some embodiments, the reactant pulse comprises generating a plasma and wherein the reactant comprises one or more plasma-generated species. Without the subject matter of the present disclosure being bound to any particular theory or mode of operation it is noted that plasma pulses may “treat” the precursor in the gas phase or chemisorbed or physisorbed on the substrate which may create many (re) active sites. By using a plasma, e.g., using a plasma gas such as H₂, it is possible to have a H rich C layer with large SP₃ content. Without the subject matter of the present disclosure being limited by any particular theory or mode of operation, it is noted that H can react with photoresist during post exposure bake and causing additional cross-linking of the photoresist, hence resulting in dose reduction (e.g., for metal organic resist).

In some embodiments, the plasma employs a plasma gas that comprises a noble gas.

In some embodiments, the noble gas comprises argon.

In some embodiments, the plasma gas further comprises hydrogen.

In some embodiments, the plasma gas substantially consists of a noble gas such as argon. In some embodiments, the plasma gas substantially consists of a noble gas and hydrogen. In some embodiments, the plasma gas substantially consists of argon and hydrogen.

In some embodiments, the plasma gas substantially consists of Ar. In some embodiments, the plasma gas substantially consists of He. In some embodiments, the plasma gas substantially consists of Ar and H₂. In some embodiments, the plasma gas substantially consists of Ar and N₂. In some embodiments, the plasma gas substantially consists of Ar, H₂, and N₂. In some embodiments, the plasma gas substantially consists of He and H₂. In some embodiments, the plasma gas substantially consists of He, H₂, and N₂. In some embodiments, the plasma gas substantially consists of Ar, H₂, and formic acid. In some embodiments, the plasma gas substantially consists of Ar, N₂, and formic acid.

In some embodiments, the plasma can be a remote or an indirect plasma, and the plasma-generated species to which the substrate is exposed can substantially consist of radicals. Such approaches can be referred to as radical-enhanced atomic layer deposition (RE-ALD). Any plasma gas as disclosed herein can be employed in a remote or indirect plasma configuration. In some embodiments, the plasma gas comprises a mixture of argon and H₂. When a remote or indirect plasma is employed, the substrate can be separated from the plasma by means of a mesh, a perforated plate, or the like.

In some embodiments, the underlayer substantially consists of amorphous carbon. Amorphous carbon can comprise non-crystalline carbon and hydrogen.

In some embodiments, the underlayer comprises at least 50 atomic percent carbon. In some embodiments, the underlayer comprises at least 60 atomic percent carbon. In some embodiments, the underlayer comprises at least 70 atomic percent carbon. In some embodiments, the underlayer comprises at least 80 atomic percent carbon. In some embodiments, the underlayer comprises at least 90 atomic percent carbon. In some embodiments, the underlayer comprises at least 95 atomic percent carbon. In some embodiments, the underlayer comprises at least 99 atomic percent carbon. In some embodiments, the underlayer substantially consists of carbon and hydrogen.

In some embodiments, the underlayer comprises from at least 20 atomic percent to at most 60 atomic percent hydrogen and from at least 40 atomic percent to at most 80 atomic percent carbon. In some embodiments, the underlayer comprises from at least 30 atomic percent to at most 50 atomic percent hydrogen and from at least 50 atomic percent to at most 70 atomic percent carbon.

In some embodiments, the underlayer comprises one or more elements that have a high capture cross section for extreme ultraviolet (EUV) radiation.

In some embodiments, the underlayer comprises tin (Sn). In some embodiments, the underlayer comprises an element selected from the list consisting of F, Ge, Hf, In, Sb, Sn, I, Te, Cs, and Bi.

In some embodiments, ones from the plurality of deposition cycles further comprise a post precursor purge. The post precursor purge can be executed immediately after the precursor pulse.

In some embodiments, ones from the plurality of deposition cycles further comprise a post plasma purge, the post plasma purge can be executed immediately after the reactant pulse.

A purge can comprise exposing the substrate to an inert gas such as a noble gas such as argon.

In some embodiments, the precursor pulse comprises a plurality of micro precursor pulses.

In some embodiments, the reactant pulse comprises a plurality of micro reactant pulses.

Precursor and reactant can be commonly referred to as reactive species, and corresponding pulses can be referred to as reactive pulses.

In other words, in some embodiments, a reactive pulse can comprise a plurality of subsequent micro pulses that comprise alternatingly exposing the substrate to a reactive species and to an inert or substantially inert gas, i.e., a purge gas.

For example, when a capacitively coupled direct plasma is used, employing micro pulses can be used to control the number of ions reaching the substrate surface and thereby control the dangling bonds in the carbon film. This can, in turn, influence etch rate of the carbon film and it can influence adhesion to a resist that is deposited onto that film. The resist can be a spin-on resist or a dry resist. Spin-on resists can be applied to a substrate via spin coating. Dry resists can be applied to a substrate via vapor phase deposition techniques such as molecular layer deposition. Additionally, or alternatively, micro pulses can be employed to control one or more of growth rate and composition of the carbon film.

In some embodiments, the cyclical deposition process results in an initial underlayer that has an initial sp3 carbon content, and the cyclical deposition process can be followed by subjecting the substrate to a treatment step. The treatment step can result in a treated underlayer that has a treated sp3 carbon content. The treated sp3 carbon content can be larger than the initial sp3 carbon content.

In some embodiments, the treatment step can be carried out in-situ. In some embodiments, the treatment step can be carried out in the same reaction chamber as the cyclical deposition process. In some embodiments, the treatment step can be carried out in a different reaction chamber, a treatment reaction chamber, that is comprised in a cluster system that also comprises a deposition reaction chamber in which the cyclical deposition process is carried out. Thus, the cyclical deposition process and the treatment step can be sequentially carried out without any intervening vacuum break. For example, the substrate is not exposed to pressures higher than 100 Torr, or 10 Torr, or 1 Torr during transfer between deposition reaction chamber and treatment reaction chamber.

Advantageously, a treatment step as disclosed herein can be employed for tuning adhesion of resist to the underlayer, such that resist can be easily removed without causing pattern collapse.

In some embodiments, the treatment step comprises a plasma treatment step that comprises generating a treatment plasma that employs a plasma gas. The plasma treatment step can comprise exposing the substrate to one or more active treatment species. Advantageously, a treatment can improve, i.e., reduce critical dimension, i.e., smaller features can be printed without defects, i.e., pattern collapse.

In some embodiments, the plasma gas comprises a noble gas. Additionally, or alternatively, the noble gas can comprise one or more of an oxygen reactant, a nitrogen reactant, a boron reactant, and a carbon reactant. Suitable oxygen reactants can be selected from O₂, O₃, H₂O, H₂O₂, N₂O, NO, NO₂, and NO₃. Suitable nitrogen reactants can be selected from N₂, NH₃, and N₂H₂. Suitable carbon reactants can comprise hydrocarbons such as alkanes such as CH₄, formic acid, isopropanol. Suitable boron reactants can comprise borohydrides such as B₂H₆, B₃H₆N₃, Suitable sulfur reactants can comprise hydrogen sulfide (H₂S), Carbon disulfide (CS₂), Sulfur (S). Suitable phosphorus reactants can comprise Phosphine (PH₃), white phosphorus.

It shall be understood that tBu stands for tert-butyl, and that Me stands for methyl.

In some embodiments, the plasma gas comprises a noble gas and hydrogen. For example, the plasma gas can comprise Ar and H₂.

In some embodiments, the plasma gas comprises a noble gas and an SiOC precursor. In some embodiments, the precursor comprises Si and C. In some embodiments, the precursor comprises a Si—C bond. In some embodiments, the precursor comprises an alkyl, alkenyl, alkynyl, or aryl group attached to silicon. In some embodiments, the precursor comprises an alkylamino group attached to Si. In some embodiments, the alkylamino is selected from —NMe₂, —NEt₂, —NEtMe, —NHtBu, —N(iPr)₂, —N(sBu)₂, —N(SiMe₃)₂, —N(SiEt₃)₂. In some embodiments, the precursor comprises an alkoxy group attached to Si. In some embodiments, the alkoxy group is selected from —OMe, —OEt, —OiPr, —OtBu, —OsBu, —OtPn, —OSiMe₃, or —OSiEt₃.

In some embodiments, the SiOC precursor is selected from the list consisting of Dimethyldimethoxysilane, Tetramethyldimethoxydisiloxane, (3-Methoxypropyl)trimethoxysilane, Bis(diethylamino)silane, hexamethyldisilazane, and Dimethyltrimethylsilylamine.

In some embodiments, the SiOC precursor is selected from the following: SiH(NMe₂)₃, Si(NMe₂)₄, Si(NEtMe)₄, SiCl(NMe₂)₃, SiH₂(NEt₂)₂, SiH₂(NHtBu)₂, SiH₃(N(iPr)₂), SiH₃(N(sBu)₂), Si₂(NHEt)₆, Si(OEt)₄, SiMe₃(NMe₂), SiMe₂(NMe₂)₂, SiH₂(NEtMe)₂.

For example, the oxygen plasma can comprise an O₂ plasma, i.e., a plasma that employs a plasma gas that comprises O₂. For example, the oxygen plasma can comprise a H₂O plasma, i.e., a plasma that employs a plasma gas that comprises H₂O, e.g., a plasma gas that substantially consists of Ar and H₂O. In some embodiments, the plasma gas comprises O₂ and Ar. In some embodiments, the plasma gas substantially consists of O₂ and Ar. Advantageously, it was found that treating an underlayer according to an embodiment of the present disclosure for 2 seconds with an O₂ plasma can result in improved adhesion of metalorganic resist, in particular, features having a smaller critical dimension could be printed without defects. Without the subject matter of the present disclosure being bound by any particular theory or mode of operation, it is believed that this may be related to the underlayer having an increased polar component of its surface energy. It is assumed that these plasmas reduce H terminated carbon atoms at the surface and increase O on the surface. In some embodiments, these specific plasmas employ a plasma power less than 100 W for a 300 mm wafer, and may last up to 5 seconds, e.g., for 2-5 seconds, to avoid damage to the surface and from modifying deeper layers of the underlayer. Other conditions may be modified to tune the stability of the plasma and the degree of change to the underlayer. A small penalty to the dose-reduction due to the surface modification is sometimes seen, but the dose reduction is still high and is considered an acceptable trade-off for the adhesion improvement.

In some embodiments, the treatment comprises converting some or all of the sp2 carbon in an underlayer according to an embodiment of the present disclosure into sp3 carbon. Such a conversion can be achieved by one or more of introduction of a treatment precursor into a deposition process or as a post-deposition exposure step. In embodiments where the treatment precursor is introduced into a deposition process, it can be introduced periodically (i.e., as a pulse) in an ALD-type pulse/purge scheme. In such a scheme, the treatment precursor could be introduced each cycle or after some number of repeated cycles within a super-cycle. In some embodiments, the treatment precursor could be introduced continuously during a deposition process. In some embodiments, the treatment precursor could be delivered concurrently with another precursor compound. In some embodiments, the treatment precursor could be delivered concurrently or adjacently to a plasma gas exposure step.

In some embodiments, the treatment precursor comprises an alkylating, such as a strong alkylating agent.

In some embodiments, alkylating agents can include diiodo-substituted hydrocarbons such as diiodo alkanes such as diiodomethane, and 1,2-diiodoethane.

In some embodiments, the alkylating agent comprises a sulfonate such as methyl fluorosulfonate, methyl methanesulfonate, and methyl trifluoromethane sulfonate.

In some embodiments, the alkylating agent comprises a sulfate, such as an alkyl sulfate, such as dimethyl sulfate.

In some embodiments, the alkylating agent comprises a dihydrocarbyl carbonate such as a dialkyl carbonate such as dimethyl carbonate.

In some embodiments, the treatment precursor comprises a chemical capable of performing a transfer hydrogenation reaction.

For example, in some embodiments, the treatment precursor can comprise an organic acid such as formic acid.

In some embodiments, the treatment precursor comprises an alcohol, such as an alkyl alcohol, such as isopropanol.

In some embodiments, the treatment precursor comprises a cyclical hydrocarbon.

In some embodiments, the treatment precursor comprises a cyclical diene such as a substituted or unsubstituted hexadiene, such as a compound selected from the list consisting of 1,3-cyclohexadiene, 1,4-cyclohexadiene, and 1-methyl-1,4-cyclohexadiene.

In some embodiments, the treatment precursor comprises one or more aromatic rings. For example, the treatment precursor can comprise one or more of 9,10-dihydroanthracene or hydroquinone.

In some embodiments, the treatment precursor can comprise one or more of hydrazine and a hydrazine derivative. For example, the treatment precursor can be selected from the list consisting of hydrazine, dimethylhydrazine, and tert-butylhydrazine.

In some embodiments, the treatment precursor can comprise a dihydrocarbyl hydroxylamine, such as a dialkyl hydroxylamine, such as diethyl hydroxylamine.

In some embodiments, the treatment precursor comprises a diimide.

In some embodiments, the treatment comprises annealing the substrate. In some embodiments the substrate is thermally annealed for a period of about 1 to about 15 minutes. In some embodiments the substrate is thermally annealed at a temperature of about 200 to about 500° C. In some embodiments the thermal anneal step comprises two or more steps in which the substrate is thermally annealed for a first period of time at a first temperature and then thermally annealed for a second period of time at a second temperature.

In some embodiments, the treatment comprises exposing the underlayer to reactive species generated from plasma. For example, reactive species generated from hydrogen-and argon-comprising plasma can be used. The underlayer may be exposed to plasma from about 1seconds to about 1 minute, such as from about 1 second to about 30 seconds, or from about 5seconds to about 30 seconds, or for about 1 second to about 15 seconds, or from about 3 seconds to about 20 seconds, for example for about 5 seconds, for about 10 seconds, for about 20 seconds or for about 30 seconds. A plasma power of at least about 20 W, or at least about 50 W, such as from about 20 W to about 100 W, such as 30 W, 50 W or 70 W, may be used. The suitable plasma power and duration of the plasma exposure may be determined experimentally.

In some embodiments, the treatment step comprises exposing the underlayer to electromagnetic radiation, such as microwaves, infrared radiation, visible light, ultraviolet light, or extreme ultraviolet light, or X-rays.

In some embodiments, forming an underlayer comprises executing a plurality of super cycles. Ones from the plurality of super cycle comprise a cyclical deposition process and a treatment step. The cyclical deposition process and the treatment step can be executed in the same reaction chamber or in different reaction chambers comprised in the same vacuum system. The cyclical deposition process can comprise a cyclical deposition process as described elsewhere herein. The treatment step can comprise a treatment as described elsewhere herein. Advantageously, performing such super cycles can yield an underlayer with a particularly high sp3 carbon content.

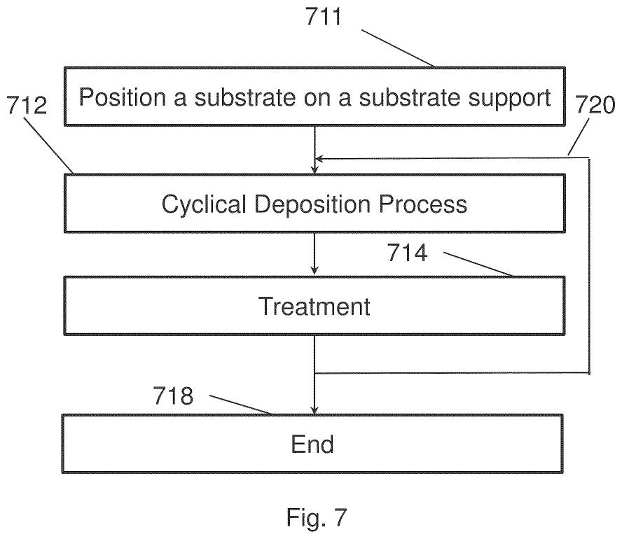

A super cycle process according to an embodiment of the present disclosure is described by reference to FIG. 7. The super cycle process comprises positioning 711 a substrate on a substrate support. Then, the super cycle process comprises executing a plurality of super cycles 720. Ones from the plurality of super cycles 720 comprise executing a cyclical deposition process 712 as described herein and executing a treatment 714 as described herein. After a suitable number of super cycles have been executed, the method ends.

During EUV exposure, metal centers may absorb EUV radiation. Thus, photoelectrons may be generated. Cascading photoelectrons may generate primary and secondary electrons. Secondary electrons may break radiation-sensitive ligands away from metal centers. An underlayer formed by means of an embodiment of the present disclosure may increase secondary electron flow to a resist. When exposed resist is exposed to air, broken ligands may react with at least one of H₂O and O₂ in air to form hydroxy groups. When the exposed resist is then subjected to a heat treatment, e.g., using a post exposure bake, hydroxy groups may condensate to form metal oxide. Unexposed resist may then be removed using a developer to form a pattern.

Without the subject matter of the present disclosure being bound by any particular theory or mode of operation, it is noted that dose reduction can occur during through a variety of mechanisms. For example, for extreme ultraviolet (EUV) lithography, dose reduction can occur through effects during exposure, or during a post exposure bake, or during resist development, or through a combination of various effects.

Embodiments of cyclical deposition processes are now described with respect to timelines shown in the figures.

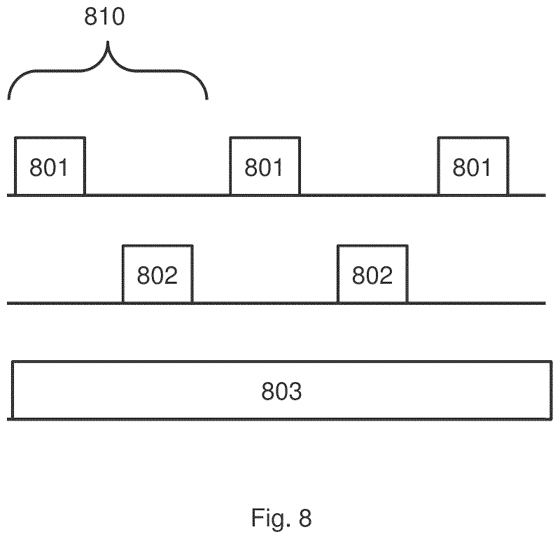

A cyclical deposition process according to a method according to an embodiment of the present disclosure is described with respect to FIG. 8. This cyclical deposition process comprises a plurality of deposition cycles 810. Ones from the plurality of deposition cycles 810 comprise a precursor pulse 801 and a plasma pulse 802. A precursor pulse comprises exposing a substrate to a precursor. A plasma pulse comprises generating a plasma and exposing the substrate to one or more active species such as ions and radicals. Subsequent precursor and plasma pulses may or may not be separated by purges. Throughout the cyclical deposition process, the substrate may be exposed to a reactive gas 803. In some embodiments, the reactive gas can comprise one or more of H₂, an oxygen reactant as described herein, a nitrogen reactant as described herein, and a boron reactant as described herein.

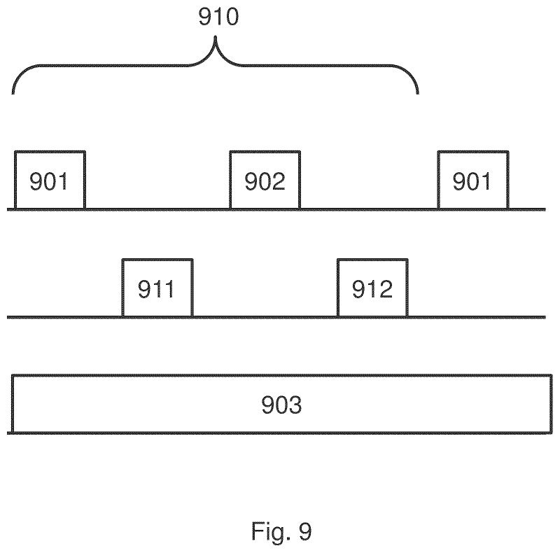

A cyclical deposition process according to another method according to an embodiment of the present disclosure is described with respect to FIG. 9. This cyclical deposition process comprises a plurality of deposition cycles 910. Ones from the plurality of deposition cycles comprise a first precursor pulse 901, a second precursor pulse 902, a first plasma pulse 911, and a second plasma pulse 912. The first plasma pulse 911 is executed after the first precursor pulse 901 and before the second precursor pulse 902. The second plasma pulse 912 is executed after the second precursor pulse 902. Subsequent pulses may be separated by purges. A first precursor pulse 901 can comprise exposing the substrate to a first precursor. A second precursor pulse 902 can comprise exposing the substrate to a second precursor. The first and second precursors 901,902 may be different and include precursors as described herein. The first and second plasma pulses 911,912 may employ any suitable plasma gas. The plasma gas used during the first and second plasma pulses may be the same or different. Throughout the cyclical deposition process, the substrate may be exposed to a reactive gas 903. In some embodiments, the reactive gas can comprise one or more of H₂, an oxygen reactant as described herein, a nitrogen reactant as described herein, and a boron reactant as described herein.

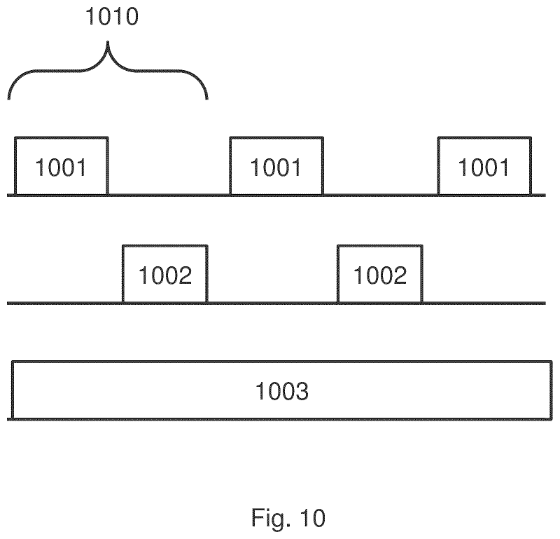

A cyclical deposition process according to a method according to another embodiment of the present disclosure is described with respect to FIG. 10. This cyclical deposition process comprises a plurality of deposition cycles 1010. Ones from the plurality of deposition cycles 1010 comprise a precursor pulse 1001 and a plasma pulse 1002. The precursor pulse comprises simultaneously exposing a substrate to a first precursor and to a second precursor. The first and second precursors are different. A plasma pulse comprises generating a plasma and exposing the substrate to one or more active species such as ions and radicals. Subsequent precursor and plasma pulses may or may not be separated by purges. Throughout the cyclical deposition process, the substrate may be exposed to a reactive gas 1003. In some embodiments, the reactive gas can comprise one or more of H₂, an oxygen reactant as described herein, a nitrogen reactant as described herein, and a boron reactant as described herein.

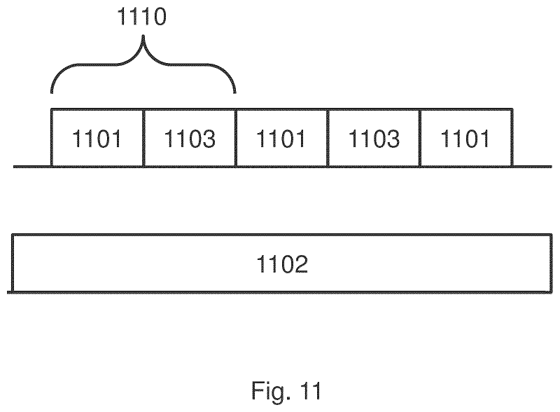

A cyclical deposition process according to a method according to another embodiment of the present disclosure is described with respect to FIG. 11. This cyclical deposition process comprises a plurality of deposition cycles 1110. Ones from the plurality of deposition cycles 1110 comprise a precursor pulse 1101 and a purge 1103. The purge 1103 separates subsequent precursor pulses 1101 in time and/or in space. The precursor pulse 1101 comprises exposing a substrate to a precursor. The purge 1103 comprises exposing the substrate to a purge gas. Throughout the cyclical deposition process, this particular method comprises continuously generating a plasma and exposing the substrate to one or more active species such as ions and radicals. The plasma can employ any suitable plasma gas, such as a plasma gas as described herein.

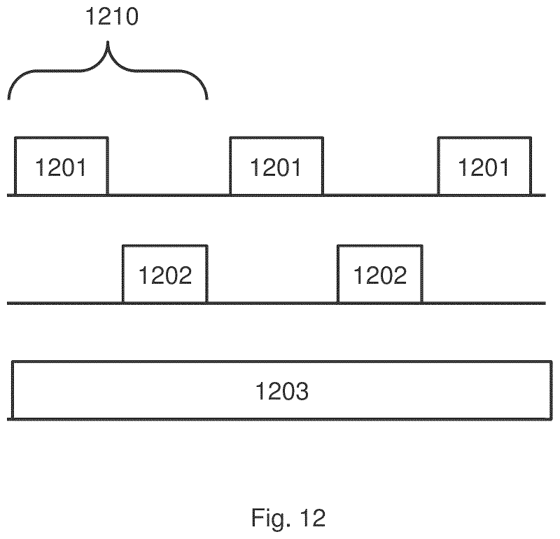

A cyclical deposition process according to a method according to another embodiment of the present disclosure is described with respect to FIG. 12. This cyclical deposition process comprises a plurality of deposition cycles 1210. Ones from the plurality of deposition cycles 1210 comprise a first precursor pulse 1201 and a second precursor pulse 1202. The first precursor pulse 1201 comprises exposing a substrate to a first precursor. The second precursor pulse 1202 comprises exposing a substrate to a second precursor. The first and second precursors are different. Subsequent first and second precursor pulses may or may not be separated by purges. Throughout the cyclical deposition process, a plasma is generated 1203 and the substrate is exposed to one or more active species such as ions and radicals.

A cyclical deposition process according to a method according to another embodiment of the present disclosure is described with respect to FIG. 13. This cyclical deposition process comprises a plurality of deposition cycles 1310. Ones from the plurality of deposition cycles 1310 comprise a precursor pulse 1301 and a reactant pulse 1302. The precursor pulse 1301 comprises exposing a substrate to a precursor. Suitable precursors are described elsewhere herein.

The reactant pulse 1302 comprises exposing a substrate to a reactant. In some embodiments, the reactant can comprise one or more of H₂, an oxygen reactant as described herein, a nitrogen reactant as described herein, and a boron reactant as described herein. Subsequent precursor and reactant pulses may or may not be separated by purges. Throughout the cyclical deposition process, a plasma is generated 1303 and the substrate is exposed to one or more active species such as ions and radicals.

Further described herein is a structure that comprises a substrate, an underlayer overlying the substrate, and a photosensitive layer overlying the underlayer. The underlayer is formed by means of a method as described herein.

Further described herein is a system that comprises a reaction chamber, a substrate support, and a controller that is constructed and arranged for causing the system to execute a method as described herein.

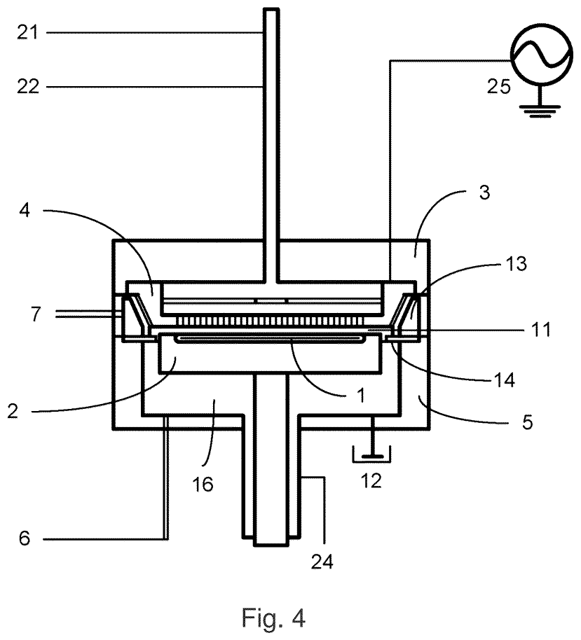

The presently provided methods may be executed in any suitable apparatus, including in a reactor as shown in FIG. 4. Similarly, the presently provided structures may be manufactured in any suitable apparatus, including a reactor as shown in FIG. 4. FIG. 4 is a schematic view of an embodiment of a plasma-enhanced atomic layer deposition (PEALD) apparatus, desirably in conjunction with controls programmed to conduct the sequences described below, usable in some embodiments of the present disclosure. In this figure, by providing a pair of electrically conductive flat-plate electrodes (2,4) in parallel and facing each other in the interior (11) (reaction zone) of a reaction chamber (3), applying RF power (e.g. at 13.56 MHz and/or 27 MHz) from a power source (25) to one side, and electrically grounding the other side (12), a plasma is excited between the electrodes. A temperature regulator may be provided in a lower stage (2), i.e., the lower electrode. A substrate (1) is placed thereon and its temperature is kept constant at a given temperature. The upper electrode (4) can serve as a shower plate as well, and a reactant gas and/or a dilution gas, if any, as well as a precursor gas can be introduced into the reaction chamber (3) through a gas line (21) and a gas line (22), respectively, and through the shower plate (4). Additionally, in the reaction chamber (3), a circular duct (13) with an exhaust line (17) is provided, through which the gas in the interior (11) of the reaction chamber (3) is exhausted. Additionally, a transfer chamber (5) is disposed below the reaction chamber (3) and is provided with a gas seal line (24) to introduce seal gas into the interior (11) of the reaction chamber (3) via the interior (16) of the transfer chamber (5) wherein a separation plate (14) for separating the reaction zone and the transfer zone is provided. Note that a gate valve through which a wafer may be transferred into or from the transfer chamber (5) is omitted from this figure. The transfer chamber is also provided with an exhaust line (6). In some embodiments, depositing the underlayer and curing the underlayer is done in one and the same reaction chamber. In some embodiments, forming the underlayer and curing the underlayer is done in separate reaction chambers comprised in one and the same system.

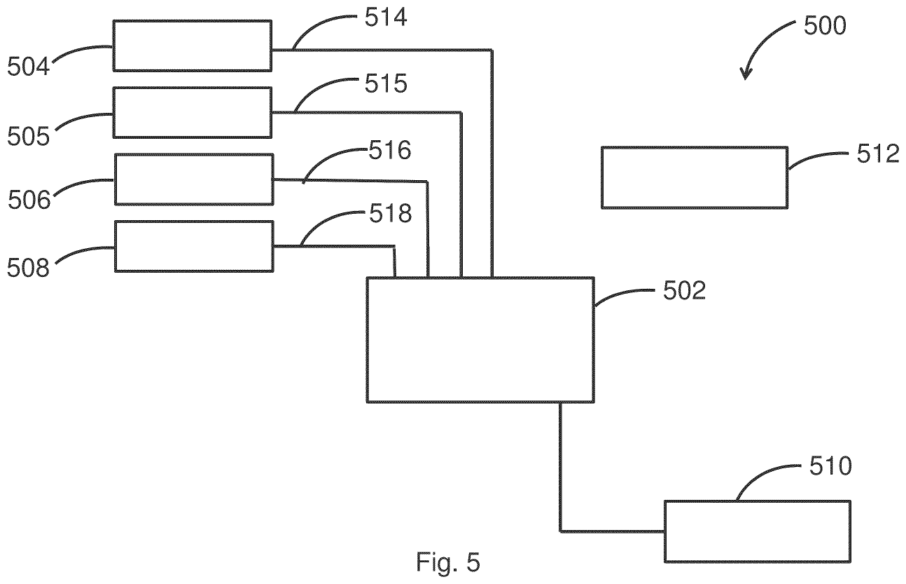

FIG. 5 illustrates another embodiment of a system 500 in accordance with exemplary embodiments of the disclosure. The system 500 can be configured to perform a method as described herein and/or form a structure or device portion as described herein. In the illustrated example, the system 500 includes one or more reaction chambers 502, a first precursor gas source 504, a reactant gas source 506, an optional further precursor source 508, an exhaust 510, and a controller 512. In some embodiments, the system further comprises at least one of a second precursor gas source (not shown) and a second dopant precursor gas source (not shown). The reaction chamber 502 can include an ALD reaction chamber.

The first precursor gas source 504 can include a vessel and one or more precursors as described herein-alone or mixed with one or more carrier (e.g., noble) gases. The reactant gas source 506 can include a vessel and one or more dopant precursors as described herein-alone or mixed with one or more carrier gases. The optional further precursor source 508 can include one or more further precursors or reactants as described herein.

Although illustrated with four gas sources 504-508, the system 500 can include any suitable number of gas sources. The gas sources 504-508 can be coupled to the reaction chamber 502 via the lines 514-518, which can each include flow controllers, valves, heaters, and the like. The exhaust 510 can include one or more vacuum pumps.

The controller 512 includes electronic circuitry and software to selectively operate valves, manifolds, heaters, pumps, and other components included in the system 500. Such circuitry and components operate to introduce precursors, reactants, and purge gases from the respective sources 504-508. The controller 512 can control timing of gas pulse sequences, temperature of the substrate and/or reaction chamber, pressure within the reaction chamber, and various other operations to provide proper operation of the system 500. The controller 512 can include control software to electrically or pneumatically control valves to control flow of precursors, reactants, and purge gases into and out of the reaction chamber 502. The controller 512 can include modules such as a software or hardware component, e.g., a FPGA or ASIC, which performs certain tasks. A module can advantageously be configured to reside on the addressable storage medium of the control system and be configured to execute one or more processes as described herein.

Other configurations of the system 500 are possible, including different numbers and kinds of precursor and oxygen reactant sources and optionally further including purge gas sources. Further, it will be appreciated that there are many arrangements of valves, conduits, precursor sources, and purge gas sources that may be used to accomplish the goal of selectively feeding gases into the reaction chamber 502. Further, as a schematic representation of a system, many components have been omitted for simplicity of illustration, and such components may include, for example, various valves, manifolds, purifiers, heaters, containers, vents, and/or bypasses.

During operation of the system 500, substrates, such as semiconductor wafers (not illustrated), are transferred from, e.g., a substrate handling system to the reaction chamber 502. Once the substrate(s) are transferred to the reaction chamber 502, one or more gases from the gas sources 504-508, such as precursors, reactants, carrier gases, and/or purge gases, are introduced into the reaction chamber 502.

In an exemplary embodiment, a carbon layer was formed using a plasma-enhanced cyclical deposition process that comprised a plurality of deposition cycles comprising a precursor pulse and a plasma pulse. Subsequent pulses were separated by purges. 1,2,4-trimethylbenzene was used as a precursor, and a plasma gas comprising dihydrogen and argon was employed. The substrate was maintained at a temperature of at least 75° C. to at most 400° C. Pressure was maintained between 300 and 1200 Pa. A capacitively coupled direct plasma was employed using an RF power of at least 50 to at most 200 W. The substrate was a 300 mm silicon wafer.

In an exemplary embodiment, a carbon underlayer was formed using a plasma-enhanced cyclical deposition process that comprised a plurality of deposition cycles comprising a precursor pulse and a plasma pulse. Subsequent pulses were separated by purges. Octane was used as a precursor. Argon was used as a plasma gas. The substrate was maintained at a temperature of 75° C. during the plasma-enhanced cyclical deposition process. In some embodiments, a mixture comprising argon and H₂ can be employed as a plasma gas. The substrate on which the carbon underlayer is formed can comprise an ashable hard mask (AHM). The AHM can comprise amorphous carbon that is deposited using plasma-enhanced chemical vapor deposition. In some embodiments, a resist is formed, e.g., deposited, on the underlayer. Suitable resists include metalorganic resist (MOR). Although AHM is also a carbon material, the octane based material has a clearly beneficial effect and reduces the effective dose for this resist. Currently this film alone can decrease dose by as much as 25% with good roughness. The film requires no more than 10 minutes to deposit per wafer.

In an exemplary embodiment, an underlayer according to an embodiment of the present disclosure having a thickness of around 10 nm was formed on a PECVD-deposited carbon layer. The polar component of the surface energy of the underlayer is particularly low. Ar and Ar/O₂ plasmas have been found to be effective at increasing the polar component of the surface energy, and this has been seen to increase the adhesion of metalorganic resist in lithography line-space exposures by reducing collapse of the lines. It is assumed that these plasmas reduce H terminated carbon atoms at the surface and increase O on the surface.

In an exemplary embodiment, it has been found that a plasma containing SiOC precursor such as 3-methoxypropyl) trimethoxysilane can also increase the polar component with similar results. The SiOC in these conditions does not grow well on the carbon so very little of the SiOC is added to the top surface. Therefore it is seen as more of a surface modification rather than adding another underlayer and so does not greatly penalize the dose reduction.

In an exemplary embodiment, underlayer treatments using N₂ and H₂ plasmas have also been tested and can modify the surface as well with results depending on the underlayer in question. Using other inert gases like He or reactants like O₃ and H₂O as part of the plasma are also possible.

Further described herein is a method of forming an underlayer that comprises providing a substrate on a substrate support, providing a liquid spin-on formulation that comprises at least one of a precursor and a reactant as described herein. The substrate is subsequently made to rotate while the liquid spin-on formulation is poured on the substrate, to form an untreated underlayer. The untreated underlayer may then be subjected to a treatment as described herein to form an underlayer.

1. A method of forming an underlayer for lithographic patterning, the method comprising:
providing a substrate to a reaction chamber; and
executing a cyclical deposition process, the cyclical deposition process comprising a plurality of deposition cycles, ones from the plurality of deposition cycles comprising a precursor pulse that comprises exposing the substrate to a precursor, ones from the plurality of deposition cycles further comprising a reactant pulse that comprises exposing the substrate to a reactant,
wherein the underlayer comprises carbon.

2. The method according to claim 1, wherein at least 50 atomic percent of the carbon comprised in the underlayer is sp3 carbon.

3. The method according to claim 1, wherein the precursor comprises an aromatic compound.

4. The method according to claim 3, wherein the precursor is selected from a list consisting of benzene, alkylbenzene, toluene, ethylbenzene, xylene, durene, aniline, phenol, benzoic acid, biphenyl, mesitylene, styrene, toluidine, toluic acid, cresol, and, naphthalene.

5. The method according to claim 3, wherein the precursor comprises 1,2,4-trimethylbenzene.

6. The method according to claim 1, wherein the precursor comprises an alkane.

7. The method according to claim 6, wherein the precursor comprises octane.

8. The method according to claim 1, wherein the reactant pulse comprises generating a plasma and wherein the reactant comprises one or more plasma-generated species.

9. The method according to claim 8, wherein the plasma employs a plasma gas that comprises a noble gas.

10. The method according to claim 9, wherein the noble gas comprises argon.

11. The method according to claim 9, wherein the plasma gas further comprises hydrogen.

12. The method according to claim 1, wherein the underlayer substantially consists of amorphous carbon.

13. The method according to claim 1, wherein ones from the plurality of deposition cycles further comprise a post precursor purge, the post precursor purge being executed after the precursor pulse.

14. The method according to claim 1, wherein ones from the plurality of deposition cycles further comprise a post reactant purge, the post reactant purge being executed after the reactant pulse.

15. The method according to claim 1, wherein the cyclical deposition process results in an initial underlayer having an initial sp3 carbon content, and wherein the cyclical deposition process is followed by subjecting the substrate to a treatment step, the treatment step resulting in a treated underlayer having a treated sp3 carbon content, the treated sp3 carbon content being larger than the initial sp3 carbon content.

16. The method according to claim 15, wherein the treatment step comprises a plasma treatment step that comprises generating a treatment plasma, and exposing the substrate to one or more active treatment species.

17. The method according to claim 16 wherein the treatment plasma comprises one or more of an argon plasma and an oxygen plasma.

18. The method according to claim 1, wherein the reactant pulse comprises a plurality of micro reactant pulses.

19. A structure comprising a substrate, an underlayer overlying the substrate, and a photosensitive layer overlying the underlayer, wherein the underlayer is formed by the method according to claim 1.

20. A system comprising a reaction chamber, a substrate support, and a controller that is constructed and arranged for causing the system to execute the method according to claim 1.
